(19) United States
(12) Patent Application Publication
(10) Pub. No.: US 2004/0035363 A1
(43) Pub. Date: Feb. 26, 2004

(54) Device and a method for the formation of gradient layers on substrates in a vacuum chamber

(76) Inventors: Stafan Braun, Dresden (DE); Hermann Mai, Dresden (DE)

Correspondence Address: ANDREW R. BASIL, Young & Basile, P.C., Suite 624, 3001 West Big Beaver Road, Troy, MI, 48084, US

(21) Appl. No.: 10/646,543

(22) Filed: Aug. 21, 2003

(30) Foreign Application Priority Data
Aug. 23, 2002 (DE) 102 39 163.7

(51) Int. Cl. C23C 16/00; C23C 14/00

(52) U.S. Cl. 118/720; 118/723 VE

(57) ABSTRACT

The invention relates to a device and a method for the formation of gradient layers on substrates in a vacuum chamber by means of which the gradient layers having increased efficiency and reduced residual ripple of the surface can be-obtained. The solution according to the invention is then designed such that at least one plasma source or by means of evaporation a particle current is directed upon the surface of the substrate to be coated within the vacuum chamber. A mask having discretely arranged perforations is disposed between a particle source and the substrate. The mask has a constant thickness and is allowed to be oscillatorily moved by means of a drive along at least one axis with respect to the substrate in a plane. The ratio of the free cross-sections of the perforations being discretely present within the mask, and of the, intermediate web surfaces varies 'per unit of area over the total surface or on areas of this mask. However, the distance between the surface of the substrate and the mask can also be of different size, solely or alternatively, over the total surface or of surface areas.

The invention relates to a device and a method as well for the formation of gradient layers on substrates in a vacuum chamber, and to the use of the device according to the invention for the fabrication of X-ray optics elements.

The solution according to the invention is suitable for the fabrication of gradient layers, and accordingly multilayer systems as well which in particular can be employed for the fabrication of X-ray optics elements as well as for the use with electromagnetic radiation within the wavelength range of the extreme ultraviolet radiation.

Then, the individual layers may have layer thicknesses in the range of between 0.2 nm and 1 μm.

In particular, with the short wavelengths of matter in question of the electromagnetic radiation high demands are placed on the equivalent local layer thicknesses of the gradient layers to ensure the desired layer and coating properties, respectively.

Thus, it is well-known to form regularly constructed multilayer reflectors (LSM=layered synthetic microstructure) on substrate surfaces, wherein equivalent alternating layer systems made of materials having a high or lower electron density (e.g. SiO₂, Mo, Si, C) between the latter barrier layers can also be formed again, respectively, can be used with a number of periods of up to 1000 periods. The barrier layers are allowed then to be extremely thin, and have layer thicknesses in the range of between 0.2 to 5 nm.

However, with solutions which are known per se, problems arise for the fabrication of gradient layers and equivalent multilayer systems, respectively, with such substrates the surfaces of which to be coated are curved at least in areas to further achieve beam shaping properties in addition to the reflection and monochromatization.

Thus, from R. Dietsch et al. in “PULSED LASER DEPOSITION (PLD)—An Advanced State for Technical Applications”, Opt. and Quantum Electronics 27 (1995), page 1385, for example, it is known for the fabrication of so-called “Göbelspiegel” (Goebel mirrors) to form a nanometer type multilayer system on an correspondingly curved surface of a substrate, in which the respective substrate is moved translatorily with a varied velocity along an axis with respect to a flow source of particles.

From U.S. Pat. No. 5,993,904 it is known for the fabrication of such graded layers to use a mask element which is designed to be fixed with the substrate to be coated. With this mask element, a plurality of channels having a different length is provided, wherein the longitudinal variation of the channels is selected in a continuous manner. According to the length of the channels an equivalent volume flow rate of particles is allowed to reach through them the substrate surface to be coated, and accordingly, in connection with longer channels a lower layer thickness, and in connection with correspondingly shorter channels a higher layer thickness can be formed.

However, by the use of a mask element having such channels, the achievable coating rate on the surface of the substrate will be reduced since a portion of the flow rate of particles deposits on the mask element and inside the channels.

Furthermore, with such a solution the gradient layer formed on the surface of substrates or an appropriate multilayer system cannot avoid residual ripple which negatively affects the optical and X-ray optics properties.

Therefore, it is an object of the invention to propose a solution wherein gradient layers having an increased efficiency and reduced residual ripple of the surface of the formed gradient layers can be obtained.

According to the invention, this object is achieved with a device comprising the features of claim 1, and a method according to claim 16 as well. An advantageous use results according to claim 23 for the fabrication of X-ray optics elements which particularly advantageously include beam shaping properties as well.

Features mentioned in the subordinate claims represent advantageous aspects and improvements of the invention. With the solution according to the invention, the surface of a substrate is coated within a vacuum chamber wherein a flow rate of particles utilized for the coating is formed from a particle source and directed upon the surface of the substrate to be coated through a mask having discretely arranged perforations and disposed between the particle source and substrate.

Plasma sources, targets and baskets, e.g. are suitable particle sources.

On that occasion, the mask is preferably formed plate-shaped, and has a constant thickness, generally.

Then, the mask and the substrate are moved relative to each other. This motion is allowed to occur oscillatorily along at least one axis. However, it is also possible during the coating process to perform such oscillatory motions along two axes aligned orthogonally to each other.

However, it is also possible to perform the relative motion in the form of a circular path such that the respective perforations of the mask perform a circular path motion.

With such a relative motion of the mask and substrate, the residual ripple can be reduced evidently (e.g. with the factor of 10).

The graded layer thickness can be obtained with the mask to be used according to the invention by means of a respective variation of the ratio of free cross-sections of the perforations being discretely provided in the mask, and the intermediate web surfaces per unit of area. Such graded layer thicknesses can be present over the total surface, however, on areas of the mask as well to form equivalent gradients of layer thicknesses on the total surface or merely on areas of the surface to be coated.

However, gradients of layer thicknesses can also be obtained alone or in addition to the previously described way by means of a corresponding variation of the distance between the surface of the substrate and the mask. Thus, for example, the mask can be obliquely aligned at an inclined angle toward the substrate surface, however, or an obliquely inclined substrate surface can be used with a mask aligned orthogonally to the respective flow rate of particles.

However, the mask can be curved completely or merely in areas in a concave and convex manner, respectively.

As a rule, it will be advantageous to form the perforations being discretely arranged within the mask with identical free cross-sections and identical cross-sectional geometries as well.

The free cross-sections of the perforations are allowed to be formed in a circular, hexagonal, octagonal or even elliptical manner.

With hexagonal or octagonal cross-sectional shapes of the perforations it is possible that unequal edge lengths have been formed in order to obtain elongated free cross-sections of the perforations such as with elliptical shapes as well. In particular, this is favourable if the mask to be used according to the invention has been aligned at an obliquely inclined angle or with a curved formation with respect to the respective substrate surface. Thus, the respective angle of inclination at the corresponding perforation may be compensated for the passage of the flow rate of particles.

Frequently, it may be favourable to continuously provide the variation of the ratio of the free cross-sections of the perforations with the intermediate web surfaces per unit of area along an axis.

Particularly in this case the perforations can be formed in a column and line arrangement within the mask. In this case it is also suitable for the perforations to be staggered to each other in adjacent lines or columns.

It is also possible for this ratio to be varied from the inside radially toward outwards, for example, originating from the centre or centre of gravity of the surface of the mask.

However, the ratio of the free cross-section surfaces and of the intermediate web surfaces per unit of area can also be varied under consideration of a substrate surface being aligned at an obliquely inclined angle or curved, thus considering the different distances between the mask and substrate surface.

The translatory oscillatory motion between the mask and substrate should preferably be performed in parallel with the alignment of the respective lines and/or columns of perforations.

The path travelled between the inversion points during such an oscillatory motion should correspond to the central distance of centres or centres of gravity of the surface of the perforations of a mask.

However, the same dimensioning can also be selected for the diameter of the circular path motions which carry out the individual perforations of the mask.

The flow rate of particles used for coating can be generated in vacuum with CVD methods or else PVD methods known per se. Thus, for example, the electro-beam evaporation, the PLD method and ion-supported methods can be employed.

Magnetron sputtering has become apparent as suitable to obtain relatively large-area and homogenous coatings, in particular.

Successively, multilayer systems can be formed with several sources of particle flow rates in a common vacuum chamber.

In addition to the relative motion to be employed between the mask and substrate it is also advantageous to additionally move the substrate and mask together with respect to the plasma source and/or a target which in turn can be advantageously obtained through a common rotation about an axis of rotation.

For a relative motion of the mask and substrate the most different propulsion concepts can be used. Thus, it is possible to use conventional mechanical drives including gears and without additional gears which can also be combined with the drive for the common motion of the substrate and mask.

However, in particular for an oscillatory translatory relative motion it may be advantageous to use at least one piezo actuator which implements the oscillatory motion including a suitable path between the inversion points by means of a lever system, as the case may be.

With the invention, it is possible to form almost any gradients of layer thickness, and however locally limited gradients of layer thickness in the individual layers or multilayer systems on substrate surfaces. Layer thicknesses within the range of >0.2 up to 1 μm area are allowed to be implemented.

The achievable residual ripple is so small such that interferences with reflections of X-radiation can be avoided.

Most differently formed substrate surfaces are allowed to be coated in a graded form wherein variations of layer thickness in different axial alignments can be further obtained.

In the following, the invention shall be explained in more detail by way of example, wherein

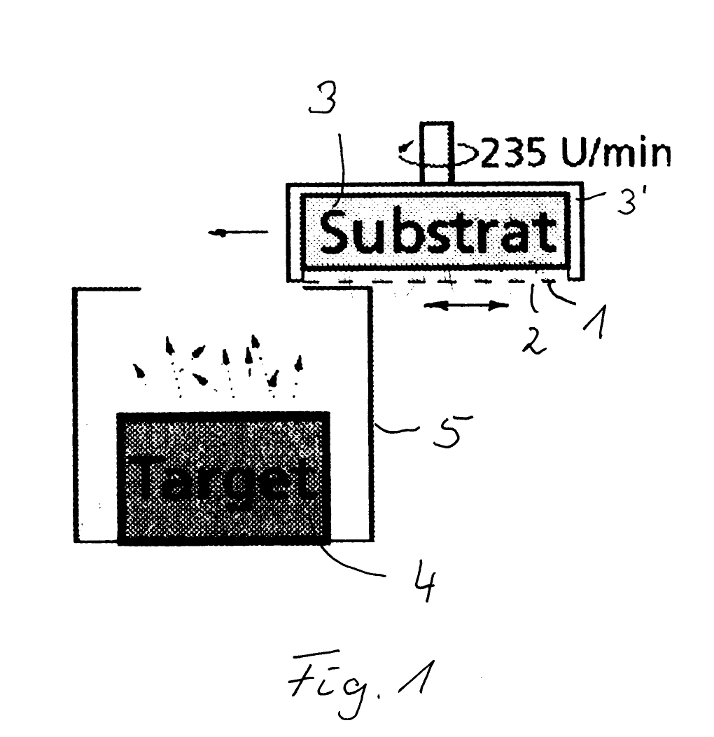

FIG. 1 diagrammatically shows an example for a device according to the invention; and

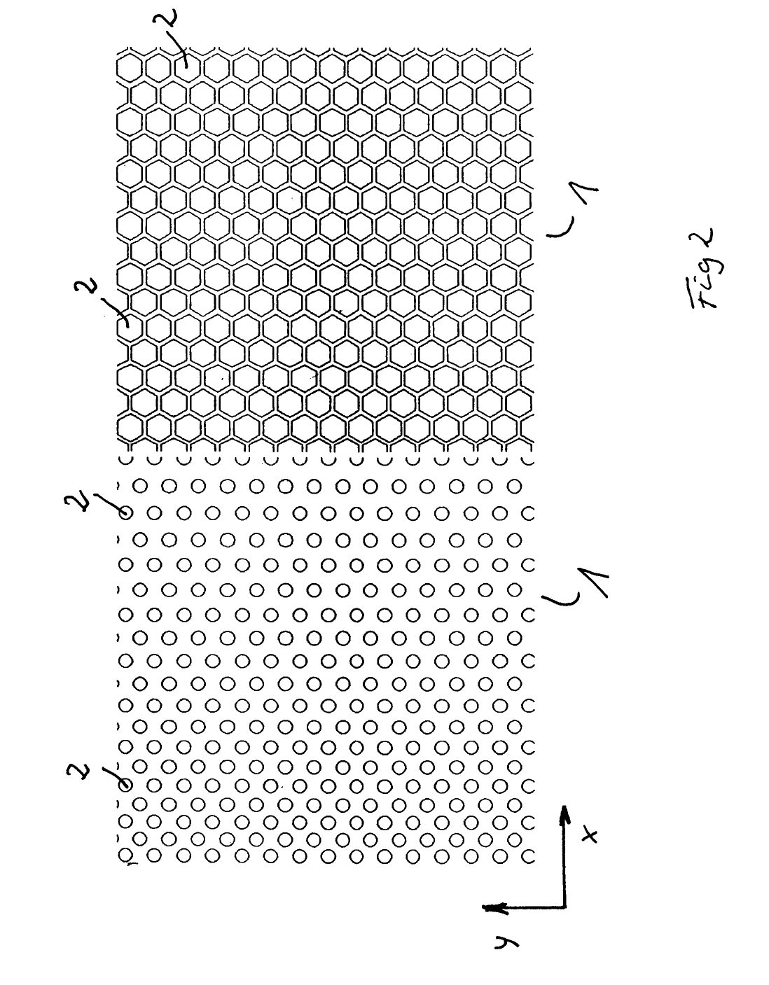

FIG. 2 shows two examples for masks which can be employed with the invention.

In FIG. 1, a substrate 3 including a substrate holder 3 is shown abandoning the illustration of a vacuum chamber.

Between a target 4 which a particle current is directed from upon the surface of the substrate 3 to be coated, and the surface of the substrate 3 to be coated, a mask 1 to be employed according to the invention is present, which can be moved relative to the substrate 3 by means of a drive not shown as well. A respective oscillatory reciprocating motion is intimated with the double arrow which also applies to the perforations formed within the mask 1 for the illustration in FIG. 1.

Substrate 3 including the mask 1 is allowed to be moved with the substrate holder 3′ during a simultaneous rotation about the axis of rotation of the substrate holder 3′ across the target 4, and in the range of influence of the particle current as indicated with the portion aligned to the left.

To avoid undesirable layer depositions or the influence of further plasma sources in the vacuum chamber a shield 5 is present which ensures that the particle current is allowed to selectively pass towards the surface of the substrate 3 to be coated.

In this example, the distance between the mask 1 having the perforations 2 toward the surface of the substrate 3 is of appr. 5 mm

The path travelled between inversion points of the mask 1 moved relatively with respect to the substrate 3 has been adjusted to 2 mm.

The already mentioned motion of the substrate holder 3′ including substrate 3 together with the mask 1 has been controlled such that a homogenous coating of constant layer thickness would have been formed on the surface of the substrate 3 without using the additional mask 1.

In FIG. 2 two examples for masks 1 to be used according to the invention are illustrated side by side.

On that occasion, in the mask 1 illustrated on the left, circular perforations 2 have been formed, and in the mask 1 illustrated on the right, hexagonal perforations 2 have been formed.

With the two examples of the masks 1, the ratio of the free cross-sectional surfaces of the perforations 2 to the intermediate web surfaces in the X-direction is reduced continuously.

With the example illustrated on the left, therefore the distances of perforations 2 arranged in series become greater from the left to the right, and with the example illustrated on the right, in the same axial direction the web widths between the perforations 2 having hexagonal free cross-sections become greater. From this it results that the current density of the particle current impacting upon the surface of substrate 3 is diminished in the respective direction of the X-axis, and since the transition of this ratio is brought about continuously, the layer thickness also reduces in a continuous manner, correspondingly.

Due to the relative motion which is performed between the mask 1 and substrate 3, a uniform layer gradient can be achieved with the substantially reduced residual ripple as already mentioned in the general part of the description.

The plate shaped material for the masks 1 should have a maximum thickness of 1 mm, and the perforations 2 are allowed to be fabricated by means of laser cutting methods or even by conventionally stamping.

However, the thickness of the masks 1 can also be distinctly below 1 mm, wherein in such cases preferably metal foils are allowed to be employed. Since such foils have a reduced strength, in these cases it is advantageous to clamp the foils into a frame.

In the examples of masks shown in FIG. 2 the perforations 2 have a diameter of 2 mm, and a cross-sectional diagonal of 2 mm in the example shown on the right, wherein the distances increase from line to line of the perforations 2 each in the range of 0.05 to 0.1 mm in the direction of the X-axis.

1. A device for the formation of gradient layers on substrates in a vacuum chamber by means of a particle flow formed from at least one plasma source or by vaporization, which is directed upon the substrate surface to be coated,
wherein a mask having discretely located perforations is disposed between a particle source and a substrate, characterized in that
said mask (1) of constant thickness can be moved oscillatorily by means of a drive along at least one axis with respect to said substrate (3) in a plane, and the ratio of free cross-sections of said perforations (2) being discretely present in said mask (1), and the intermediate web surfaces of said mask (1) per area unit is varied over the total surface or on areas of said mask (1),
and/or the distance between the surface of said substrate (3) and said mask (1) is different in size over the total surface of surface areas.

2. A device according to claim 1, characterized in that said perforations (2) of said mask (1) each have identical free cross-sections and cross-sectional geometries.

3. A device according to claim 1 or claim 2, characterized in that said free cross-sections of said perforations (2) are formed in a circular, hexagonal, octagonal or elliptical form.

4. A device according to at least any one of the preceding claims, characterized in that the ratio of said free cross-sections of said perforations (2) and said intermediate web surfaces per unit of area are continuously varied along at least one axis.

5. A device according to at least any one of the preceding claims, characterized in that said perforations are formed in a column and line arrangement within said mask (1).

6. A device according to claim 5, characterized in that said perforations are located offset to each other in the adjacent columns or lines.

7. A device according to at least any one of the preceding claims, characterized in that the distances of said perforations (2) are varied along at least one axis.

8. A device according to at least any one of the preceding claims, characterized in that the surface of said substrate (3) is aligned at an angle obliquely inclined with respect to said mask (1) and/or is curved.

9. A device according to at least any one of the preceding claims, characterized in that with a curved substrate surface the ratio of the free cross-sections of said perforations (2) and said intermediate web surface per unit of area takes into consideration the respective distance of said substrate surface and/or the inclination of said substrate surface and said mask (1).

10. A device according to at least any one of the preceding claims, characterized in that said mask (1) is aligned at an angle obliquely inclined with respect to the surface of said substrate (3) and/or is curved.

11. A device according to at least any one of the preceding claims, characterized in that the direction of motion of said oscillatory motion is aligned in parallel to the respective lines and/or columns of perforations (2).

12. A device according to at least any one of the preceding claims, characterized in that the plasma source is a magnetron sputtering source.

13. A device according to at least any one of the preceding claims, characterized in that said substrate (3) and said mask (1) are movable together relative with respect to said plasma source and/or said target (4).

14. A device according to claim 13, characterized in that said substrate (3) and said mask (1) rotate about a common axis of rotation.

15. A device according to at least any one of the preceding claims, characterized in that said drive for said oscillatory relative motion between said substrate (3) and said mask (1) is at least a piezo actuator.

16. A method for the formation of gradient layers on substrates in a vacuum chamber by means of which a particle current formed from a plasma source or by means of evaporation of a target material will be directed through a mask located between said particle source and said substrate, in which perforations are formed, characterized in that the local thickness of said formed layer on the substrate surface is defined by predetermined locally adapted ratios of free cross-sections and said intermediate web surfaces per unit of area and/or by holding of particular distances between the surface of said substrate (3) and said mask (1), and said mask (1) having a constant thickness is moved oscillatorily along at least one axis relative to said substrate (3) in a plane.

17. A method according to claim 16, characterized in that with an oscillatory motion the path to be travelled between inversion points or during a circular path motion the diameter corresponds to the mean distance of the centre or centre of gravity of said perforations (2).

18. A method according to claim 16 or claim 17, characterized in that said relative motion or said circular path motion is performed in the plane of the mask.

19. A method according to at least any one of claims 16 to 18, characterized in that a gradient multilayer system having at least two different layer materials is formed on the surface of said substrate (3).

20. A method according to at least any one of claims 16 to 19, characterized in that one or several gradient layer(s) formed one above another will be formed on predetermined areas of the surface of said substrate 3).

21. A method according to at least any one of claims 16 to 20, characterized in that the layer(s) is (are) formed by means of magnetron sputtering.

22. A method according to at least any one of claims 16 to 21, characterized in that said substrate (3) and said mask (1) are moved together with respect to said particle source (4).

23. Use of a device according to any one of claims 1 to 15 for the fabrication of X-ray optics elements.
